(19) United States
(12) Patent Application Publication
(10) Pub. No.: US 2024/0413036 A1
(43) Pub. Date: Dec. 12, 2024

(54) SEMICONDUCTOR DEVICE AND SEMICONDUCTOR MODULE

(71) Applicant: Murata Manufacturing Co., Ltd., Kyoto-fu (JP)

(72) Inventors: Atsushi KUROKAWA, Nagaokakyo-shi (JP); Hisatoshi KAWABATA, Nagaokakyo-shi (JP); Akira FUJIHARA, Nagaokakyo-shi (JP); Hiroshi YAMADA, Nagaokakyo-shi (JP)

(73) Assignee: Murata Manufacturing Co., Ltd., Kyoto-fu (JP)

(21) Appl. No.: 18/810,032

(22) Filed: Aug. 20, 2024

Related U.S. Application Data
(63) Continuation of application No. PCT/JP2023/006712, filed on Feb. 24, 2023.

(30) Foreign Application Priority Data
Feb. 28, 2022 (JP) 2022-029466

(51) Int. Cl. H01L 23/36; H01L 23/00; H01L 23/31; H01L 23/488

(52) U.S. Cl. CPC H01L 23/36; H01L 23/3135; H01L 24/16; H01L 23/488; H01L 2224/16227

(57) ABSTRACT

A device layer is on a first surface which is one surface of a first insulating layer. The device layer includes a transistor including source regions and drain regions, a source contact electrode connected to a source contact region on surfaces of the source regions, a drain contact electrode connected to a drain contact region on surfaces of the drain regions, wires, and vias. An insulating member is bonded to a second surface of the first insulating layer opposite to the first surface. A conical surface whose apex is located on the second surface, whose central axis is a straight line perpendicular to the second surface, and whose generatrix is a half-line extending toward the insulating member at an angle of 45° with respect to the central axis is defined as a criterion conical surface.

### CROSS-REFERENCE TO RELATED APPLICATIONS

This application claims benefit of priority to International Patent Application No. PCT/JP2023/006712, filed Feb. 24, 2023, and to Japanese Patent Application No. 2022-029466, filed Feb. 28, 2022, the entire contents of each are incorporated herein by reference.

### BACKGROUND

### Technical Field

The present disclosure relates to a semiconductor device and a semiconductor module.

### Background Art

In a structure in which a semiconductor device is flip-chip mounted on an interposer (a module substrate), a technology for enhancing heat dissipation characteristics from a transistor is disclosed in Japanese Unexamined Patent Application Publication No. 2007-214602. The semiconductor device includes a metal plate bonded to the top surface of a semiconductor element mounted on the module substrate. The semiconductor element and the metal plate are covered with a sealing resin.

### SUMMARY

When the metal plate is bonded to the top surface of the semiconductor element, the electromagnetic field distribution in the semiconductor element is disturbed by the effect of the metal plate during high frequency operation of the semiconductor element. Thus, the high-frequency characteristics of the semiconductor element deteriorate. Accordingly, the present disclosure provides a semiconductor device capable of suppressing the deterioration of heat dissipation characteristics from a transistor and the deterioration of high-frequency characteristics. Also, the present disclosure provides a semiconductor module including such a semiconductor device.

A semiconductor device according to an aspect of the present disclosure includes a first insulating layer; and a device layer that includes a transistor arranged on a first surface which is one surface of the first insulating layer and including a plurality of source regions and a plurality of drain regions, a source contact electrode connected to a source contact region on surfaces of the plurality of source regions, a drain contact electrode connected to a drain contact region on surfaces of the plurality of drain regions, a plurality of wires, and a plurality of vias. The semiconductor device further includes a plurality of bumps arranged on the device layer; and an insulating member bonded to a second surface of the first insulating layer opposite to the first surface. A conical surface whose apex is located on the second surface, whose central axis is a straight line perpendicular to the second surface, and whose generatrix is a half-line extending toward the insulating member at an angle of 45° with respect to the central axis is defined as a criterion conical surface. Also, when a direction perpendicular to the second surface is regarded as a thickness direction, an entire range in the thickness direction of a side surface of the insulating member is located outside the criterion conical surface in at least a partial range in a peripheral direction, wherein the apex of the criterion conical surface is a point on the second surface directly below a geometric center of a minimum encompassing rectangle having a smallest area encompassing all of the plurality of source contact regions and the plurality of drain contact regions.

A semiconductor module according to another aspect of the present disclosure includes the semiconductor device described above; a module substrate including a land on which the semiconductor device is mounted and to which each of the plurality of bumps of the semiconductor device is connected; and a sealing resin covering the semiconductor device.

The heat generated by the transistor reaches the insulating member via the first insulating layer. The heat reaching the insulating member moves toward the opposite surface of the insulating member while spreading laterally (in the in-plane direction of the second surface). Most of the heat moving in the insulating member moves inside the criterion conical surface. The width of the heat transfer path is not constrained by the side surface of the insulating member in a cross section that includes the central axis of the criterion conical surface and intersects the side surface located outside the criterion conical surface. Thus, the deterioration of the heat dissipation characteristics using the insulating member as the heat transfer path is suppressed.

Further, since the insulating member is bonded to the second surface of the first insulating layer, even when a conductive member is arranged in the heat transfer path, the conductive member is separated from the device layer by at least a distance corresponding to the thickness of the insulating member. Therefore, the deterioration of the high-frequency characteristics of the circuit including the transistor in the device layer is suppressed.

### BRIEF DESCRIPTION OF THE DRAWINGS

FIG. 1A is a schematic view showing the planar positional relationship of each component of a semiconductor device according to the first embodiment, and FIG. 1B is a schematic view showing another example of the planar positional relationship of each component of the semiconductor device according to the first embodiment;

FIG. 2 is a cross-sectional view showing a part of the semiconductor device and a semiconductor module according to the first embodiment;

FIGS. 3A, 3B and 3C are cross-sectional views each showing a stage during the manufacturing process of the semiconductor device according to the first embodiment;

FIG. 4A is a perspective view schematically showing a minimum encompassing rectangle of a transistor region and an insulating member, and FIGS. 4B and 4C are cross-sectional views schematically showing the minimum encompassing rectangle of the transistor region and the insulating member, the minimum encompassing rectangle being used to explain the size of the insulating member;

FIG. 5A is a cross-sectional view of a semiconductor device according to a variation of the first embodiment, and FIG. 5B is a schematic view showing the positional relationship between the insulating member and a criterion conical surface at a position indicated by the dashed line 5B-5B of FIG. 5A;

FIG. 6A is a cross-sectional view of a semiconductor device according to another variation of the first embodiment, and FIG. 6B is a schematic view showing the positional relationship between the insulating member and the criterion conical surface at a position indicated by the dashed line 6B-6B of FIG. 6A;

FIG. 7 is a cross-sectional view of a semiconductor device and a semiconductor module according to a second embodiment;

FIG. 8 is a cross-sectional view of a semiconductor device and a semiconductor module according to a third embodiment;

FIG. 9 is a cross-sectional view showing a part of a semiconductor device and a semiconductor module according to a fourth embodiment; and

FIG. 10A is a schematic view showing an electric field generated by electric charges on two parallel wires, and FIG. 10B is a graph showing a calculation result of electric field intensity at positions on the x-axis.

### DETAILED DESCRIPTION

### First Embodiment

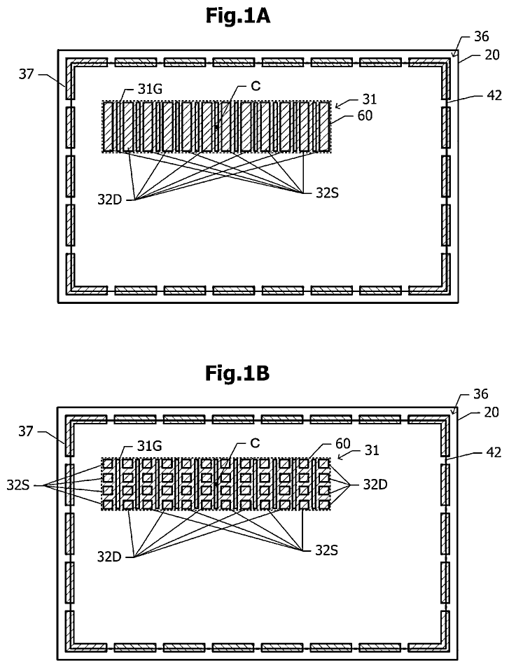

A semiconductor device and a semiconductor module according to the first embodiment will be described with reference to FIGS. 1A to 4C.

FIG. 1A is a schematic view showing the planar positional relationship of each component of the semiconductor device according to the first embodiment. A transistor 31 is arranged in the inner region of a first insulating layer 20 in plan view. The transistor 31 is a multi-finger type field effect transistor (FET). A plurality of source contact regions 32S and a plurality of drain contact regions 32D of the transistor 31 are arranged alternately in a row. A gate electrode 31G is arranged at each of the intervals between the source contact regions 32S and the drain contact regions 32D. Here, the source contact region 32S means a region where a source region and a source contact electrode of the transistor 31 come into contact, and the drain contact region 32D means a region where a drain region and a drain contact electrode of the transistor 31 come into contact. Note that the term “in plan view” means when viewed from the side where the transistor 31 is arranged with a line of sight parallel to the stacking direction of the insulating member 50 and the first insulating layer 20 described later.

As shown in FIG. 1B, the plurality of source contact regions 32S and the plurality of drain contact regions 32D may also be arranged in a direction orthogonal to the direction in which the plurality of gate electrodes 31G are aligned. For example, when the direction in which the gate electrodes 31G are aligned is a row direction, the plurality of source contact regions 32S and the plurality of drain contact regions 32D are arranged in a matrix in which the plurality of source contact regions 32S are arranged in odd columns, and the plurality of drain contact regions 32D are arranged in even columns.

The transistor 31 and wires (not shown in FIG. 1A) constitute a high-frequency circuit. Examples of the high-frequency circuit include a low-noise amplifier that amplifies a high-frequency signal, a switch that selects one filter from a plurality of filters provided for each frequency band, and the like.

The geometric center of a rectangle having the smallest area including all of the plurality of source contact regions 32S and the plurality of drain contact regions 32D in plan view (hereinafter referred to as a minimum encompassing rectangle 60) is denoted C. In FIG. 1A, the outer peripheral line of the minimum encompassing rectangle 60 is indicated by a dashed line, and the interior of the minimum encompassing rectangle 60 is hatched.

A metal layer 37 is arranged slightly inside the outer peripheral line of the first insulating layer 20 so as to surround the inner region of the first insulating layer 20 in plan view. The metal layer 37 is also called a guard ring. The metal layer 37 is separated into a plurality of portions with respect to the peripheral direction. The metal layer 37 may also be configured to be continuous in the peripheral direction so as to form a closed annular shape in plan view.

An organic protective film 42 made of an organic insulating material is arranged so as to overlap an inner region of the first insulating layer 20 (a region not including the outer edge of the first insulating layer 20) in plan view. The outer peripheral line of the organic protective film 42 is located slightly inside the outer peripheral line of the first insulating layer 20, and the organic protective film 42 is not arranged in a peripheral portion 36 of the first insulating layer 20. At least a part of the metal layer 37 is arranged outside of the organic protective film 42 (a side close to the outer edge of the first insulating layer 20) in plan view. The term “peripheral portion of the first insulating layer 20” refers to an annular region between the outer edge of the first insulating layer 20 and a closed line separated inwardly from the outer edge of the first insulating layer 20 by a predetermined distance in plan view. The “predetermined distance” is, for example, 10 μm or more and 40 μm or less (i.e., from 10 μm to 40 μm).

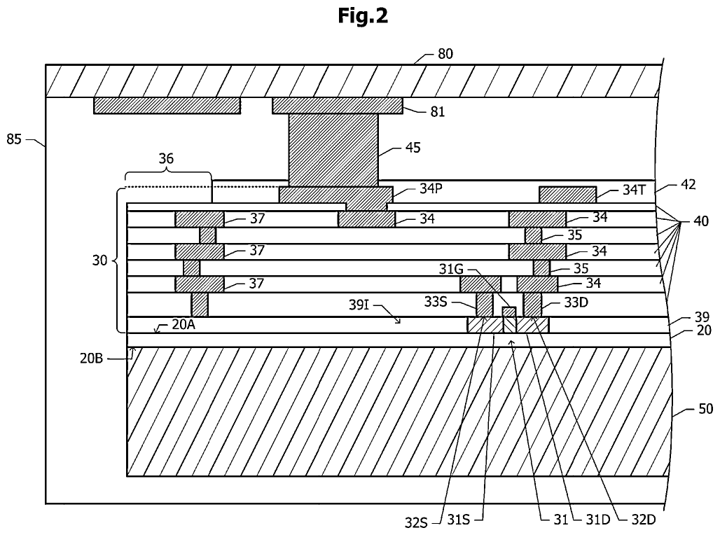

FIG. 2 is a cross-sectional view showing a part of the semiconductor device and the semiconductor module according to the first embodiment. The semiconductor device according to the first embodiment includes an insulating member 50, the first insulating layer 20, a device layer 30, the organic protective film 42, and a plurality of bumps 45. One of the plurality of bumps 45 is shown in FIG. 2. The semiconductor device is flip-chip mounted on a module substrate 80. The direction from the semiconductor device to the module substrate 80 is defined as an upward direction.

The surface of the first insulating layer 20 facing the upward direction is referred to as a first surface 20A, and the surface of the first insulating layer 20 facing the downward direction is referred to as a second surface 20B. The device layer 30 is arranged on the first surface 20A of the first insulating layer 20, and the insulating member 50 is bonded to the second surface 20B.

The insulating member 50 is formed of, for example, a polymer compound (polymer), a resin, a ceramic or the like. The polymer may contain a filler made of a high thermal conductivity material.

The device layer 30 includes an element forming layer 39 in contact with the first surface 20A of the first insulating layer 20 and a multilayer wiring layer disposed on the element forming layer 39. The element forming layer 39 is composed of an active region made of silicon and an insulating element isolation region 39I surrounding the active region. The transistor 31 is disposed within and above the active region of the element forming layer 39. The transistor 31 includes a source region 31S and a drain region 31D disposed within the active region of the element forming layer 39, and the gate electrode 31G disposed above the active region of the element forming layer 39 via a gate insulating film. The transistor 31 is a multi-finger type FET as shown in FIG. 1A; however, in FIG. 2, the transistor 31 is represented by one source region 31S, one drain region 31D, and one gate electrode 31G.

A multilayer wiring layer is arranged on the element forming layer 39. The multilayer wiring layer includes a plurality of insulating layers 40. For example, low-dielectric constant materials (Low-k materials) are used for the plurality of insulating layers 40. For example, SiN or an organic insulating material is used for the uppermost insulating layer 40.

A source contact electrode 33S and a drain contact electrode 33D are arranged in a via hole provided in the lowermost insulating layer 40 of the multilayer wiring layer. The source contact electrode 33S ohmically contacts the source region 31S in the source contact region 32S, and the drain contact electrode 33D ohmically contacts the drain region 31D in the drain contact region 32D. The source contact electrode 33S and the drain contact electrode 33D are formed of W, for example. An adhesion layer such as TiN may be arranged as needed to improve adhesion. A film made of metal silicide such as CoSi or NiSi may be formed on the surfaces of the source region 31S and the drain region 31D to reduce the resistance of the contact portion.

A plurality of wires 34 or a plurality of vias 35 are arranged on each of the second or more layers of the plurality of insulating layers 40. A damascene method, a dual damascene method, or a subtractive method is used to form the wires 34 or the vias 35. A plurality of wires 34T and a plurality of pads 34P are arranged in the uppermost wiring layer of the device layer 30. As an example, the wires 34 and 34T and the pad 34P are formed of Cu or Al, and the vias are formed of Cu or W. An adhesion layer such as TiN may be arranged as needed to prevent diffusion and improve adhesion.

The organic protective film 42 formed of an organic insulating material is arranged on the device layer 30 so as to cover the wires 34T and the pads 34P of the uppermost layer. Examples of the organic insulating material used to form the organic protective film 42 include polyimide, benzocyclobutene (BCB) and the like. The organic protective film 42 is provided with a plurality of openings to expose the upper surface of each of the plurality of pads 34P, and the bumps 45 are disposed on the pads 34P in the openings. The bump 45 is composed of, for example, an underbump metal layer and a solder layer. A Cu post structure may be arranged between the underbump metal layer and the solder layer.

The edge of the organic protective film 42 is positioned inside the edge of the device layer 30 in plan view. In other words, the organic protective film 42 is not disposed in the peripheral portion 36 of the upper surface of the device layer 30. The metal layer 37 called a guard ring is disposed in the peripheral portion of the device layer 30. At least a part of the metal layer 37 is located outside the edge of the organic protective film 42 in plan view.

By connecting the bumps 45 to the land 81 of the module substrate 80, the semiconductor device is flip-chip mounted on the module substrate 80. The semiconductor device is sealed with a sealing resin 85. On the upper surface of the uppermost insulating layer 40, the peripheral portion 36 that is not covered with the organic protective film 42 contacts the sealing resin 85.

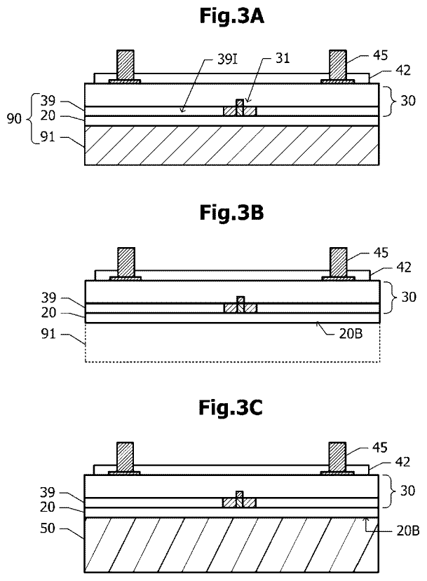

Next, a method of manufacturing the semiconductor device according to the first embodiment will be described with reference to FIGS. 3A to 3C. FIGS. 3A, 3B and 3C are cross-sectional views each showing a stage during the manufacturing process of the semiconductor device according to the first embodiment.

As shown in FIG. 3A, an SOI substrate 90 including a temporary support substrate 91 made of silicon, the first insulating layer 20 made of silicon oxide, and the element forming layer 39 made of silicon is prepared. The element isolation region 39I is formed in a part of the element forming layer 39, and the transistor 31 is formed in the active region. Further, the multilayer wiring layer of the device layer 30 is formed on the element forming layer 39. The organic protective film 42 is formed on the device layer 30, and further the bumps 45 are formed. Such structures can be formed using common wafer processes.

As shown in FIG. 3B, the temporary support substrate 91 is etched away. Before the temporary support substrate 91 is etched away, a protective tape (not shown) or the like is attached to the surface opposite to the temporary support substrate 91. By removing the temporary support substrate 91, the second surface 20B of the first insulating layer 20 is exposed.

As shown in FIG. 3C, the insulating member 50 is bonded to the second surface 20B of the first insulating layer 20. Metal bonding, direct bonding, adhesive bonding or the like can be used for such bonding.

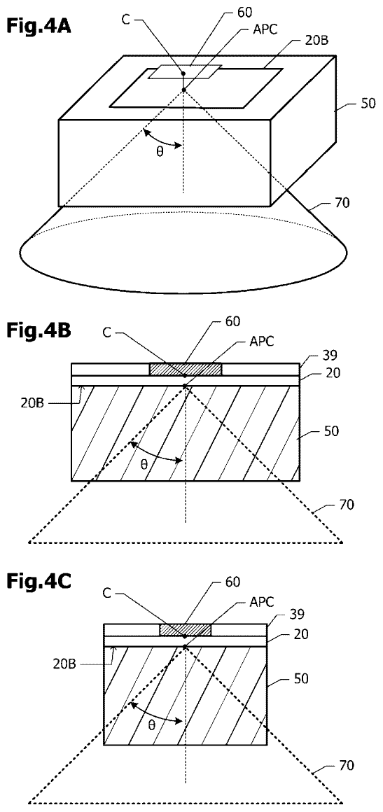

The size of the insulating member 50 will be described below with reference to FIGS. 4A, 4B, and 4C. FIG. 4A is a perspective view schematically showing the minimum encompassing rectangle 60 of a transistor region and the insulating member 50, and FIGS. 4B and 4C are cross-sectional views schematically showing the minimum encompassing rectangle 60 of the transistor region and the insulating member 50, the minimum encompassing rectangle 60 being used to explain the size of the insulating member 50.

A conical surface is defined whose apex is on the second surface 20B of the first insulating layer 20, whose central axis is a straight line perpendicular to the second surface 20B, and whose generatrix is a half-line extending toward the insulating member 50 at an angle of 45° with respect to the central axis; and such a conical surface is regarded as a criterion conical surface 70. In other words, the angle θ formed between the normal direction of the second surface 20B and the generatrix of the criterion conical surface 70 is 45°. The side surface of the insulating member 50 is located outside the criterion conical surface 70 whose apex is a point APC on the second surface 20B directly below the geometric center C of the minimum encompassing rectangle 60 of the transistor region. The point APC directly below the geometric center C overlaps the geometric center C in plan view.

The term “the side surface is located outside” means that, as shown in FIG. 4B, the entire range of the side surface of the insulating member 50 in a thickness direction is located outside the criterion conical surface 70, in which the thickness direction is a direction perpendicular to the second surface 20B. The term “the side surface of the insulating member 50” means a surface of the insulating member 50 that connects a surface bonded to the first insulating layer 20 and a surface opposite to the surface bonded to the first insulating layer 20. When the insulating member 50 is square in plan view, the insulating member 50 has four side surfaces. In the example shown in FIG. 4C, a part of the side surface of the insulating member 50 on the side of the first insulating layer 20 is located outside the criterion conical surface 70, while the remaining portion on the side far from the first insulating layer 20 is located inside the criterion conical surface 70. Therefore, in the example shown in FIG. 4C, it cannot be said that the side surface of the insulating member 50 is located outside the criterion conical surface 70.

Next, excellent effects of the first embodiment will be described. The heat generated by the transistor 31 moves into the insulating member 50 via the first insulating layer 20. Most of the heat reached into the insulating member 50 diffuses in a direction that forms an angle of 45° or less with respect to the normal direction of the second surface 20B. In other words, most of the heat transferred into the insulating member 50 from the geometric center C of the transistor region diffuses to a portion inside the criterion conical surface 70.

In particular, the temperature at the geometric center C of the minimum encompassing rectangle 60 of the transistor region tends to be the highest. Since the side surface of the insulating member 50 is located outside the criterion conical surface 70 whose apex is the point APC directly below the geometric center C, the propagation of the heat diffused in the insulating member 50 in the in-plane direction is not limited until the heat diffused in the insulating member 50 reaches the bottom surface of the insulating member 50 (the surface opposite to the surface bonded to the first insulating layer 20). Therefore, the insulating member 50 can function as a sufficient heat dissipation path.

If the temporary support substrate 91 made of silicon of the SOI substrate 90 (FIG. 3A) is left, the high-frequency characteristics of the high-frequency circuit including the transistor 31 will deteriorate due to the resistance and capacitance components of the temporary support substrate 91. In contrast, in the first embodiment, the temporary support substrate 91 is removed and the insulating member 50 is bonded. The resistance and capacitance components of the insulating member 50 are smaller than those of the temporary support substrate 91 made of silicon. Therefore, the deterioration of the high-frequency characteristics of the high-frequency circuit is suppressed.

The improvement of heat dissipation from the transistor region is particularly effective when a plurality of source regions and a plurality of drain regions of the transistor 31 are densely arranged. By the improvement of heat dissipation, the deterioration of high-frequency characteristics is also suppressed.

When a metal plate is directly bonded to the second surface 20B of the first insulating layer 20, the electromagnetic field generated from the high-frequency current flowing through the wires in the device layer 30 and the transistor 31 is disturbed by the metal plate. As a result, the high-frequency characteristics may deteriorate. The insulating member 50 used in the semiconductor device according to the first embodiment does not disturb the electromagnetic field. Therefore, the deterioration of the high-frequency characteristics can be suppressed.

A portion of the heat generated by the transistor 31 moves upward through the metal layer 37 arranged in the peripheral portion of the device layer 30. Typically, the organic protective film 42 has a lower thermal conductivity than other members of the semiconductor module. The heat transferred to the metal layer 37 reaches the sealing resin 85 through an area of the upper surface of the uppermost insulating layer 40 that is not covered by the organic protective film 42.

Since at least a part of the metal layer 37 is disposed outside the edge of the organic protective film 42, when the thermal conductivity of the sealing resin 85 is higher than the thermal conductivity of the organic protective film 42, the heat dissipation characteristics from the metal layer 37 can be enhanced. When the sealing resin 85 contains a filler having a high thermal conductivity, the heat dissipation characteristics can be further enhanced. When the uppermost insulating layer 40 has a two-layer structure of an insulating layer made of an inorganic material and an insulating layer made of an organic material, it is preferable to remove the insulating layer made of an organic insulating material in the peripheral portion 36.

Even in a configuration in which the metal layer 37 is not disposed, it is preferable to remove the organic protective film 42 in the peripheral portion 36. When the metal layer 37 is not disposed, the heat moves to the uppermost insulating layer 40 through the plurality of insulating layers 40, and the heat is transferred to the sealing resin 85 through an area of the surface of the uppermost insulating layer 40 that is not covered by the organic protective film 42. Therefore, compared with a configuration in which the entire upper surface of the uppermost insulating layer 40 is covered by the organic protective film 42, heat dissipation characteristics can be enhanced.

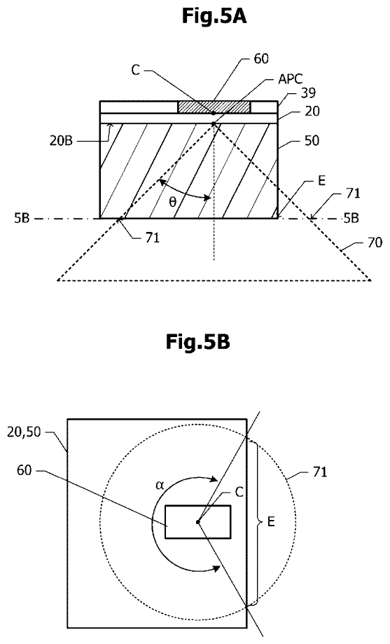

Next, a variation of the first embodiment will be described with reference to FIGS. 5A and 5B. FIG. 5A is a cross-sectional view of a semiconductor device according to the present variation. FIG. 5B is a schematic view showing the positional relationship between the insulating member 50 and the criterion conical surface 70 at a position indicated by the dashed line 5B-5B of FIG. 5A. In other words, a circumference 71 indicated by the dashed line shown in FIG. 5B is an intersection line between an imaginary plane including the bottom surface of the insulating member 50 and the criterion conical surface 70.

In the first embodiment, the side surface of the insulating member 50 is located outside the circumference 71 over the entire circumference. In contrast, in the present variation, a region near the lower end of the side surface of the insulating member 50 is located inside the criterion conical surface 70 (the circumference 71 in FIG. 5 B) in a portion E in the peripheral direction. In the present variation, of the heat generated in the minimum encompassing rectangle 60 of the transistor region, the heat diffused toward the side surface located outside the circumference 71 moves to the bottom surface of the insulating member 50 without being constrained by the side surface of the insulating member 50. Thus, higher heat dissipation characteristics can be obtained compared with a configuration in which the vicinity of the lower end of the side surface of the insulating member 50 is located inside the circumference 71 over the entire circumference. As in the present variation, it is sufficient if a part of the side surface in the peripheral direction is located outside the criterion conical surface 70 in the entire range in the thickness direction.

If the center angle α of the arc portion located inside the lower end of the side surface of the insulating member 50 of the circumference 71 is too small, there is a possibility that the sufficient heat dissipation characteristics are not ensured. To ensure sufficient heat dissipation characteristics, it is preferable to use a configuration in which the center angle α is 180° or more.

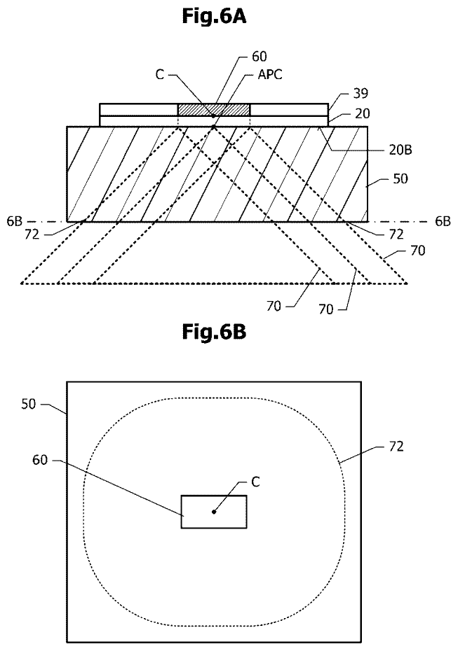

Next, another variation of the first embodiment will be described with reference to FIGS. 6A and 6B. FIG. 6A is a cross-sectional view of a semiconductor device according to the present variation. FIG. 6B is a schematic view showing the positional relationship between the insulating member 50 and the criterion conical surface 70 at a position indicated by the dashed line 6B-6B of FIG. 6A.

In the first embodiment, a point APC on the second surface 20B directly below the geometric center C of the minimum encompassing rectangle 60 of the transistor region is used as the apex of the criterion conical surface 70, which serves as a comparison to which the position of the side surface of the insulating member 50 is compared. In contrast, in the present variation, an arbitrary point in a region, on the second surface 20B, that overlaps the minimum encompassing rectangle 60 of the transistor region in plan view is used as the apex of the criterion conical surface 70.

One circular portion of the bottom surface of the insulating member 50 is cut off by one criterion conical surface 70. The region surrounded by a closed curve 72 indicated by a dashed line in FIG. 6B is a sum set of the circular regions cut off by the criterion conical surface 70 whose apex is any point in a region, on the second surface 20B, that overlaps the minimum encompassing rectangle 60 of the transistor region in plan view. The side surface of the insulating member 50 is located outside the closed curve 72 over the entire range thereof in the thickness direction. In other words, the entire range of the side surface of the insulating member 50 in the thickness direction is located outside any criterion conical surface 70 whose apex is a point in a region, on the second surface 20B, that overlaps the minimum encompassing rectangle 60 of the transistor region in plan view.

In the present variation, the heat generated at any point in the minimum encompassing rectangle 60 of the transistor region moves to the bottom surface of the insulating member 50 without being constrained by the side surface of the insulating member 50. Therefore, higher heat dissipation characteristics can be obtained.

Next, various other variations of the first embodiment will be described. In the first embodiment, the SOI substrate 90 (FIG. 3A) is used, which has a three-layer structure of a temporary support substrate 91, a first insulating layer 20 made of silicon oxide, and an element forming layer 39 made of silicon. A layer made of an insulating material other than silicon oxide, such as silicon nitride, may be arranged at the interface between the temporary support substrate 91 and the first insulating layer 20. The layer made of silicon nitride or the like has a function of protecting the first insulating layer 20 when the temporary support substrate 91 is removed by etching.

A rewiring layer may be arranged on the uppermost layer of the device layer 30. In such a case, the wires included in the rewiring layer corresponds to the wires of the uppermost layer of the device layer 30.

In the first embodiment, the outer edge of the first insulating layer 20 coincides with the outer edge of the insulating member 50 in plan view. As another variation, the outer edge of the insulating member 50 may be located outside the outer edge of the first insulating layer 20 in plan view. In other words, the first insulating layer 20 may be smaller than the insulating member 50 and included in the insulating member 50 in plan view.

In the first embodiment (FIG. 1A), the plurality of source contact regions 32S and the plurality of drain contact regions 32D of the transistor 31 are aligned alternately in a row. As another variation, a plurality of source contact regions 32S and a plurality of drain contact regions 32D may be alternately aligned in a row, and such a row is arranged in a plurality of rows. In such a case, the plurality of source contact regions 32S arranged in a plurality of rows are connected to each other, and the plurality of drain contact regions 32D arranged in a plurality of rows are connected to each other to constitute one multi-finger type FET. In such a configuration, the minimum encompassing rectangle 60 (FIG. 1A) is defined to encompass the plurality of source contact regions 32S and the plurality of drain contact regions 32D arranged in a plurality of rows.

### Second Embodiment

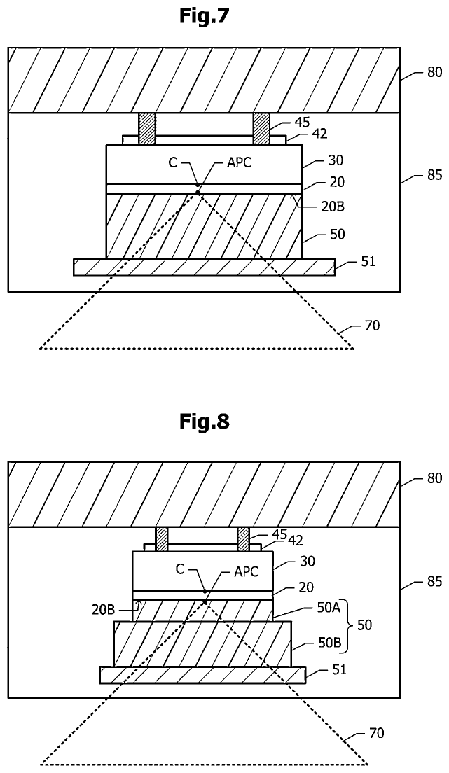

Next, a semiconductor device and a semiconductor module according to a second embodiment will be described with reference to FIG. 7. Hereinafter, the description for common configurations to the semiconductor device and the semiconductor module according to the first embodiment described with reference to FIGS. 1A to 4C will be omitted.

FIG. 7 is a cross-sectional view of the semiconductor device and the semiconductor module according to the second embodiment. In the first embodiment (FIG. 2), the bottom surface of the insulating member 50 is exposed at a stage before sealing with the sealing resin 85 (FIG. 2). After sealing, the bottom surface of the insulating member 50 contacts the sealing resin 85. In contrast, in the second embodiment, a conductive plate member 51 is bonded to the bottom surface of the insulating member 50. The thermal conductivity of the conductive plate member 51 is higher than that of the insulating member 50. For example, a copper plate is used as the conductive plate member 51. The side surface of the plate member 51 is located outside the criterion conical surface 70 whose apex is a point APC on the second surface 20B directly below the geometric center C of the minimum encompassing rectangle 60 of the transistor region. The plate member 51 is also sealed by the sealing resin 85.

Next, excellent effects of the second embodiment will be described. The heat generated by the transistor 31 (FIG. 1A and FIG. 2) is transferred to the conductive plate member 51 via the insulating member 50. Since the conductive plate member 51 has a higher thermal conductivity than that of the insulating member 50, the heat reached to the plate member 51 is quickly diffused to the entire area of the plate member 51 and then transferred to the sealing resin 85. Thus, the heat dissipation characteristics can be enhanced more than a structure in which the plate member 51 is not arranged.

Not only the first insulating layer 20 but also the insulating member 50 are arranged between the device layer 30 and the conductive plate member 51. Therefore, the high-frequency circuit in the device layer 30 is less affected by the conductive plate member 51 than a structure in which the conductive plate member is directly bonded to the second surface 20B of the first insulating layer 20. As a result, the deterioration of the high-frequency characteristics of the high-frequency circuit in the device layer 30 is suppressed.

### Third Embodiment

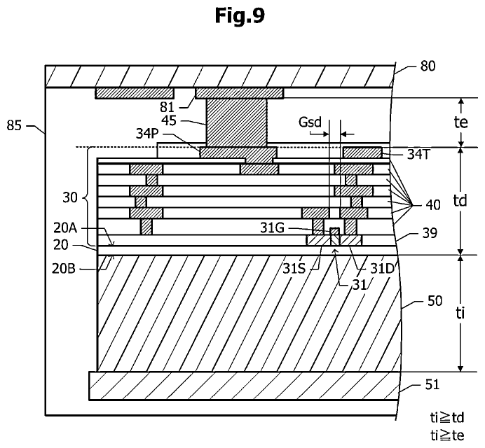

Next, a semiconductor device and a semiconductor module according to a third embodiment will be described with reference to FIG. 8. Hereinafter, the description for common configurations to the semiconductor device and the semiconductor module according to the second embodiment described with reference to FIG. 7 will be omitted.

FIG. 8 is a cross-sectional view of the semiconductor device and the semiconductor module according to the third embodiment. In the second embodiment (FIG. 7), the insulating member 50 is composed of a single member. In contrast, in the third embodiment, an insulating member 50 includes a first member 50A and a second member 50B stacked in a direction perpendicular to the second surface 20B. The first member 50A is bonded to the second surface 20B of the first insulating layer 20, and the second member 50B is bonded to the bottom surface of the first member 50A. Further, a conductive plate member 51 is bonded to the bottom surface of the second member 50B.

The first member 50A is formed of, for example, a polymer or a resin, and the second member 50B is formed of, for example, an inorganic material having a higher thermal conductivity than that of the first member 50A, and examples of such inorganic material include a ceramic. Examples of the ceramic include alumina (Al₂O₃), boron nitride (BN), aluminum nitride (AlN), silicon nitride (SiN) and the like.

The side surface of each of the first member 50A, the second member 50B and the conductive plate member 51 is located outside the criterion conical surface 70 whose apex is a point APC on the second surface 20B directly below the geometric center C of the minimum encompassing rectangle 60 (FIG. 1A) of the transistor region.

Next, excellent effects of the third embodiment will be described. From the viewpoint of heat dissipation, it is generally preferable to use an inorganic insulating material having a higher thermal conductivity than that of a polymer, a resin or the like as the insulating member 50. However, since the flatness of the second surface 20B of the first insulating layer 20 is not sufficiently high, it is difficult to bond the inorganic insulating material directly to the first insulating layer 20. In the third embodiment, since the first member 50A made of a polymer, a resin or the like is bonded to the second surface 20B of the first insulating layer 20, the difficulty of bonding is reduced. For example, the adhesive property of the polymer can be used to bond the first member 50A to the first insulating layer 20.

Since the second member 50B having a relatively high thermal conductivity is bonded to the bottom surface of the first member 50A, the heat dissipation characteristics can be enhanced compared with a configuration in which the entire insulating member 50 is formed of a polymer, a resin or the like. To enhance the heat dissipation characteristics, the thickness of the first member 50A is preferably made thinner than that of the second member 50B.

Next, various variations of the third embodiment will be described. To increase the thermal conductivity of the first member 50A made of a polymer, a resin or the like, a filler made of an inorganic material may be contained in the first member 50A. Further, in the third embodiment, a polymer is used as an example of the material of the first member 50A to facilitate the bonding of the insulating member 50 to the first insulating layer 20; however, an inorganic insulating material may be used as the material of the first member 50A with emphasis on improving heat dissipation characteristics. When an inorganic insulating material is used for the first member 50A, the first member 50A and the first insulating layer 20 may be bonded using an adhesive.

In FIG. 8, the side surfaces of the first member 50A and the second member 50B are described as flat surfaces cut perpendicular to the second surface 20B of the first insulating layer 20, but these sides are not necessarily flat surfaces perpendicular to the second surface 20B. For example, the side surfaces of the first member 50A and the second member 50B may be flat surfaces inclined to the second surface 20B or curved surfaces wavy in the thickness direction. Even in such a case, it is preferable that the entire range, in the thickness direction, of the side surfaces of the first member 50A and the second member 50B is located outside the criterion conical surface 70.

In the third embodiment, the insulating member 50 is formed by stacking two members, which are the first member 50A and the second member 50B, but it may also be formed by stacking three or more members.

### Fourth Embodiment

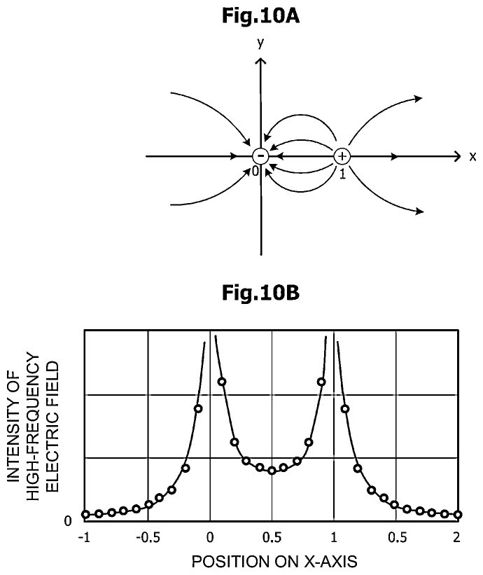

Next, a semiconductor device and a semiconductor module according to a fourth embodiment will be described with reference to FIGS. 9, 10A, and 10B. Hereinafter, the description for common configurations to the semiconductor device and the semiconductor module according to the first embodiment described with reference to FIGS. 1A to 4C will be omitted.

FIG. 9 is a cross-sectional view showing a part of the semiconductor device and the semiconductor module according to the fourth embodiment. In the fourth embodiment, a conductive plate member 51 is bonded to the bottom surface of the insulating member 50 in the same manner as the plate member 51 (FIG. 8) of the semiconductor device according to the third embodiment.

In the first embodiment (FIG. 2), there is no particular limitation on a thickness ti of the insulating member 50, a thickness td of the device layer 30, and a distance the in the thickness direction from the upper surface of the wire 34T of the uppermost layer of the device layer 30 to the land 81 of the module substrate 80. In the fourth embodiment, the preferred dimensions of the thicknesses ti and td, and the distance the will be described in terms of the effect of the conductive plate member 51 on the high-frequency circuit in the device layer 30.

The high-frequency electric field possible to be generated in the device layer 30 (FIG. 9) will be described with reference to FIGS. 10A and 10B. In the circuit of a semiconductor device that processes a high-frequency signal, the high-frequency signal is transmitted by wires that operate as a transmission line. At this time, a high-frequency electric field and a high-frequency magnetic field are generated by the current flowing through the wires respectively paired with each other. When the high-frequency signal is transmitted by two wires, a time-varying potential difference is generated between the two wires as an example.

FIG. 10A is a schematic view showing a high-frequency electric field generated by a potential difference between two parallel wires. An xy orthogonal coordinate system is defined with a plane orthogonal to the two wires as the xy plane. One wire is located at the origin of the xy coordinate system, and the other wire is located at coordinate (1,0). FIG. 10A shows a state in which the wire at the origin has a relatively low potential, and the wire at coordinate (1,0) has a relatively high potential. An electric force line is generated from the wire at coordinate (1,0) to the wire at the origin.

FIG. 10B is a graph showing a calculation result of the intensity of the high-frequency electric field at positions on the x-axis. The horizontal axis represents the position on the x-axis, and the vertical axis represents the intensity of the high-frequency electric field in an arbitrary unit. In the calculation, the wire is approximated by a linear line for simplicity, but the intensity of the high-frequency electric field shows a similar trend in the actual wire with a finite cross-sectional area. In a range where x is 0 or more and 1 or less (i.e., from 0 to 1) (the area between two wires), the intensity of the high-frequency electric field is relatively stronger than that of the surrounding area. In a range where x is 0 or less and 1 or more, the intensity of the high-frequency electric field asymptotically approaches zero toward the direction away from the wires. For example, at a point separated from the wires by a distance approximately equal to the distance between the two wires, the intensity of the high-frequency electric field is sufficiently small compared to the intensity between the two wires. Although not shown in FIG. 10B, the intensity of the high-frequency electric field at a point separated from the two wires in the y-axis direction by a distance approximately equal to the distance between the two wires is reduced to the same extent as when separated in the x-axis direction. The intensity of the high-frequency magnetic field generated by the current flowing through the two wires also shows the same distribution.

As a result, a strong high-frequency electromagnetic field is generated between and near the two wires, and the high-frequency signal is transmitted by the high-frequency electromagnetic field. If the distance from each of the two wires is equal to the distance between the two wires, the high-frequency electromagnetic field becomes sufficiently weak compared to the high-frequency electromagnetic field between the two wires. It is considered that the transmission of the high-frequency signal is almost unaffected even if a conductive member is arranged in a region where the electromagnetic field is sufficiently weakened.

In the fourth embodiment, the thickness t₁ of the insulating member 50 shown in FIG. 9 is equal to or greater than the thickness td of the device layer 30. Further, the thickness ti of the insulating member 50 is equal to or greater than the distance the.

An example of the dimensions of each component of the device layer 30 will be described below. The thickness of the element forming layer 39 is 100 nm. The thickness of each of the plurality of insulating layers 40 is 1 μm. The thickness of the wire 34T of the uppermost layer and the pad 34P in contact with the bump 45 is 3 μm. At this time, the thickness td of the device layer 30 becomes 10.1 μm. The thickness td of the device layer 30 varies depending on the number of layers of the insulating layer 40 and the thickness of the insulating layer 40, and is, for example, 2 μm or more and 30 μm or less (i.e., from 2 μm to 30 μm). For example, if the device layer 30 includes an element forming layer 39 having a thickness of 100 nm, three layers of insulating layers 40 each having a thickness of 0.5 μm, and the wire 34T and pad 34P of the uppermost layer having a thickness of 0.5 μm, the thickness td of the device layer 30 is 2.1 μm.

The distance the from the upper surface of the wire 34T of the uppermost layer of the device layer 30 to the land 81 of the module substrate 80 is approximately equal to the height of the bump 45, and is 30 μm or more and 100 μm or less (i.e., from 30 μm to 100 μm). The thickness t₁ of the insulating member 50 is 100 μm or more and 200 μm or less (i.e., from 100 μm to 200 μm).

Next, excellent effects of the fourth embodiment will be described. In the device layer 30 (FIG. 9), a large number of fine wires are arranged close to each other. Focusing on the thickness direction of the device layer 30, the high-frequency electromagnetic field generated by the wires of the relatively upper layer and the wires of the relatively lower layer is sufficiently weakened at a position far from the device layer 30 in the thickness direction by a distance equal to or greater than the thickness td of the device layer 30, as described with reference to FIG. 10B.

Since the thickness t₁ of the insulating member 50 is equal to or greater than the thickness td of the device layer 30, the distance between the conductive plate member 51 and the device layer 30 is equal to or greater than the thickness td of the device layer 30. Therefore, the conductive plate member 51 has almost no effect on the distribution of the high-frequency electromagnetic field generated from the high-frequency circuit in the device layer 30. Therefore, the deterioration of the high-frequency characteristics of the high-frequency circuit in the device layer 30 is suppressed.

The high-frequency electromagnetic field generated in the device layer 30 can also be disturbed by the conductive pattern, such as the land 81, on the module substrate 80. In general, the distance the from the wire 34T of the uppermost layer of the device layer 30 to the land 81 of the module substrate 80 is greater than the thickness td of the device layer 30. Therefore, the high-frequency characteristics of the high-frequency circuit in the device layer 30 are almost unaffected by the conductive pattern on the module substrate 80.

In the fourth embodiment, the thickness t₁ of the insulating member 50 is greater than the distance the from the wire 34T of the uppermost layer of the device layer 30 to the land 81 of the module substrate 80. As a result, the conductive plate member 51 as seen from the device layer 30 is arranged at a position further than the conductor pattern of the module substrate 80. Therefore, the effect of the conductive plate member 51 on the high-frequency characteristics of the high-frequency circuit in the device layer 30 becomes smaller than the effect of the conductor pattern on the module substrate 80.

The minimum distance between the two wires of the first layer respectively connected to the source region 31S and the drain region 31D of the transistor 31 is denoted by Gsd. The distance Gsd is equal to or less than the thickness of each of the insulating layers 40. The high-frequency signal transmitted through the wires connected to the transistor 31 has a particularly large effect on the characteristics of the high-frequency circuit. Preferably, the distance Gsd is sufficiently narrower than the thickness td of the device layer 30 so that the high-frequency electromagnetic field caused by the high-frequency signal flowing through the two wires of the first layer respectively connected to the source region 31S and the drain region 31D of the transistor 31 is less affected by the surrounding conductive members.

Further, it is preferable that the minimum distance between the wire (not shown in the cross section of FIG. 9) of the first layer connected to the gate electrode 31G of the transistor 31 and the wire connected to the source region 31S or the drain region 31D be sufficiently smaller than the thickness td of the device layer 30.

Each of the embodiments described above is an example, and it is obvious that partial substitution or combination of the configurations shown in the different embodiments is possible. Similar effects of similar configurations of the embodiments are not described sequentially for each embodiment. Further, the present disclosure is not limited to the embodiments described above. For example, it should be obvious to those skilled in the art that various modifications, improvements, combinations and the like can be made.

What is claimed is:

1. A semiconductor device comprising:
a first insulating layer;
a device layer that comprises: a transistor on a first surface which is one surface of the first insulating layer and including a plurality of source regions and a plurality of drain regions, a source contact electrode connected to a source contact region on surfaces of the plurality of source regions, a drain contact electrode connected to a drain contact region on surfaces of the plurality of drain regions, a plurality of wires, and a plurality of vias;
a plurality of bumps on the device layer; and
an insulating member bonded to a second surface of the first insulating layer opposite to the first surface,
wherein
a conical surface whose apex is located on the second surface, whose central axis is a straight line perpendicular to the second surface, and whose generatrix is a half-line extending toward the insulating member at an angle of 45° with respect to the central axis is defined as a criterion conical surface, and
when a direction perpendicular to the second surface is defined as a thickness direction, an entire range in the thickness direction of a side surface of the insulating member is located outside the criterion conical surface in at least a partial range in a peripheral direction, wherein the apex of the criterion conical surface is a point on the second surface directly below a geometric center of a minimum encompassing rectangle having a smallest area encompassing all of the plurality of source contact regions and the plurality of drain contact regions.

2. The semiconductor device according to claim 1, wherein
the entire range in the thickness direction and an entire range in the peripheral direction of the side surface of the insulating member are outside the criterion conical surface whose apex is a point on the second surface directly below the geometric center of the minimum encompassing rectangle.

3. The semiconductor device according to claim 1, wherein
the entire range in the thickness direction of the side surface of the insulating member is outside any of the criterion conical surfaces whose apex is a point in a region, on the second surface, that overlaps the minimum encompassing rectangle in plan view.

4. The semiconductor device according to claim 1, wherein the insulating member comprises:
a first member bonded to the first insulating layer; and
a second member at a position farther from the first member as seen from the first insulating layer and having a thermal conductivity higher than a thermal conductivity of the first member.

5. The semiconductor device according to claim 4, wherein
a thickness of the first member is smaller than a thickness of the second member.

6. The semiconductor device according to claim 4, wherein
the first member includes an organic insulating material and the second member is includes an inorganic insulating material.

7. The semiconductor device according to claim 4, wherein
the first member includes a polymer compound.

8. The semiconductor device according to claim 1, further comprising:
a conductive plate member bonded to a surface of the insulating member on a side opposite to a surface bonded to the first insulating layer.

9. The semiconductor device according to claim 8, wherein
the conductive plate member extends in plan view to an outside of the criterion conical surface whose apex is a point on the second surface directly below the geometric center of the minimum encompassing rectangle.

10. The semiconductor device according to claim 1, wherein
the first insulating layer includes silicon oxide.

11. The semiconductor device according to claim 1, further comprising:
an organic protective film including an organic insulating material and being on the device layer,
wherein
the plurality of bumps are respectively connected to the wires of the device layer through a plurality of openings in the organic protective film, and
the organic protective film is not in at least a part of a peripheral portion of an upper surface of the device layer.

12. The semiconductor device according to claim 11, wherein
the device layer comprises a metal layer in the peripheral portion of the device layer in plan view, and at least a part of the metal layer is on an outside of the organic protective film in plan view.

13. The semiconductor device according to claim 1, wherein
a thickness of the insulating member is equal to or greater than a thickness from a lower surface of the device layer to an upper surface of a wire of an uppermost layer included in the device layer.

14. A semiconductor module comprising:
the semiconductor device according to claim 1;
a module substrate including a land on which the semiconductor device is mounted and to which each of the plurality of bumps of the semiconductor device is connected; and
a sealing resin covering the semiconductor device.

15. The semiconductor module according to claim 14, wherein
a thickness of the insulating member is equal to or greater than a dimension in a direction perpendicular to the second surface from a wire of an uppermost layer included in the device layer to the land.

16. A semiconductor device comprising:
a first insulating layer;
a device layer including a transistor on a first surface which is one surface of the first insulating layer, a plurality of wires, and a plurality of vias;
a plurality of bumps on the device layer; and
an insulating member bonded to a second surface opposite to the first surface of the first insulating layer,
wherein when a direction perpendicular to the second surface is defined as a thickness direction, a thickness of the insulating member is equal to or greater than a thickness from a lower surface of the device layer to an upper surface of a wire of an uppermost layer included in the device layer.

17. The semiconductor device according to claim 2, wherein the insulating member comprises:
a first member bonded to the first insulating layer; and
a second member at a position farther from the first member as seen from the first insulating layer and having a thermal conductivity higher than a thermal conductivity of the first member.

18. The semiconductor device according to claim 5, wherein
the first member includes an organic insulating material and the second member is includes an inorganic insulating material.

19. The semiconductor device according to claim 5, wherein
the first member includes a polymer compound.

20. The semiconductor device according to claim 2, further comprising:
a conductive plate member bonded to a surface of the insulating member on a side opposite to a surface bonded to the first insulating layer.
